(19) United States
(12) Patent Application Publication
(10) Pub. No.: US 2014/0191622 A1
(43) Pub. Date: Jul. 10, 2014

(54) PIEZOELECTRIC COMPONENT AND METHOD FOR PRODUCING A PIEZOELECTRIC COMPONENT

(71) Applicant: ROBERT BOSCH GMBH, Stuttgart (DE)

(72) Inventor: Reinhold Melcher, Erlangen (DE)

(21) Appl. No.: 14/151,956

(22) Filed: Jan. 10, 2014

(30) Foreign Application Priority Data
Jan. 10, 2013 (DE) 10 2013 200 244.0

(51) Int. Cl. H01L 41/047; H01L 41/293

(52) U.S. Cl. CPC H01L 41/0475; H01L 41/0471; H01L 41/0477; H01L 41/293
USPC 310/366; 29/25.35

(57) ABSTRACT

A piezoelectric component (1), which serves particularly as a piezoelectric sensor or piezoelectric actuator, comprises a basic body (6) which has a first ceramic layer (7), a second ceramic layer (8) and an internal electrode layer (9). In this case, the internal electrode layer (9) is provided at least partially between the first ceramic layer (7) and the second ceramic layer (8). The basic body (6) has a bore (10) which is provided at least partially in the region of the internal electrode layers (9). Furthermore, an electrical contact element (13) is inserted at least partially into the bore (10) of the basic body (6) and is connected electrically at least indirectly to the internal electrode layer (9) in the bore (10).

### BACKGROUND OF THE INVENTION

The invention relates to a piezoelectric component, in particular a piezoelectric sensor or piezoelectric actuator, and to a method for producing such a piezoelectric component. The invention relates in particular to the field of piezoelectric components for fuel injection systems.

A fuel injector with a force sensor or pressure sensor is known from DE 10 2010 00 827 A1. In the known fuel injector, the force sensor or pressure sensor is assigned to a control space, the pressure of which determines the strokes or positions of a nozzle needle. The profile of a control space pressure can in this case be detected by the force sensor or pressure sensor.

In the configuration of a piezoelectric component, in particular of a piezoelectric pressure sensor, it is conceivable that internal electrode layers are contacted via suitable outer electrodes. However, such electrical contacting requires a plurality of materials and components and also process steps in production. This type of electrical contacting is therefore correspondingly complicated and costly. For example, in the case of a piezoelectric actuator, basic metalization can first be applied to the ground actuator and is then baked. This basic metalization can have soldered onto it a screen-like fabric, to which, in turn, the actual connecting cable can be welded.

### SUMMARY OF THE INVENTION

The piezoelectric component according to the invention and the method according to the invention have the advantage that an improved configuration of the piezoelectric component and/or more cost-effective production are/is made possible. In particular, one or more complicated outer electrode tie-ups can be avoided.

It is advantageous that the electrical contact element is fastened in the bore of the basic body by clamping. In this case, the bore can be introduced into the green product for the basic body. The bore is thus formed even before sintering. The electrical contact element can then be introduced at least partially into the bore of the green product. The electrical contact element can in this case be introduced directly into the bore of the green product. This means that the electrical contact element is introduced into the bore of the green product without metalizing paste or the like. The green product can subsequently be sintered together with the electrical contact element introduced into the bore, the electrical contact element being fastened directly in the bore of the basic body by virtue of sinter shrinkage of the green product. Fastening in this case takes place by clamping. Thus, both a mechanical connection to the basic body and an electrical connection to the internal electrode layer are made.

It is also advantageous that the electrical contact element is fastened in the bore of the basic body by means of an additive. In particular, it is advantageous that the additive is in the form of an electrically conductive additive, and that the electrical contact element is connected electrically to the internal electrode layer by means of the electrically conductive additive. In this case, a paste, in particular a metalizing paste, can be introduced into the bore of the green product before sintering. The electrical contact element is thus then introduced together with the paste into the bore of the green product. After sintering, the paste forms the additive. The electrical contact element is then fastened in the bore of the basic body by means of the additive and is connected electrically to the electrode layer preferably via the electrically conductive additive.

It is also possible, however, that the green product, into which the bore is introduced, is first sintered, and that the electrical contact element is subsequently inserted at least partially into the bore of the basic body by means of an additive, the electrical contact element being connected to the basic body in the bore by means of the additive. In this case, the additive is preferably in the form of an electrically conductive additive. Thus, both a mechanical connection to the basic body and an electrical connection to the electrode layer are ensured via the electrically conductive additive.

It is also possible, however, that the green product for the basic body is first sintered and that the bore is formed in the basic body only after sintering. The electrical contact element can then likewise be fastened in the bore of the basic body by means of an additive. In this case, at the same time, an electrical connection to the electrode layer is ensured via an electrically conductive additive.

In one possible embodiment, an axis of the bore in which the electrically conductive contact element is fastened is oriented at least approximately parallel to the internal electrode layer. Particularly in an embodiment of the basic body as a plate-shaped or disk-shaped basic body, lateral contacting can advantageously be implemented here. This embodiment is suitable particularly for the situation where the basic body has exactly one internal electrode layer. Further electrode layers can in this case be formed on the end faces of the basic body by means of metalizations.

In a further possible embodiment, it is advantageous that at least one further internal electrode layer is provided, that the bore is provided at least partially in the region of the internal electrode layer and at least partially in the region of the further internal electrode layer, and that an axis of the bore is oriented at least approximately perpendicularly to the internal electrode layer and to the further internal electrode layer. Electrical contacting of a plurality of electrode layers is thus possible. In this case, even a plurality of bores, in particular two bores, may be provided in order to contact a multiplicity of electrode layers alternately.

### BRIEF DESCRIPTION OF THE DRAWINGS

Preferred exemplary embodiments of the invention are explained in more detail in the following description, with reference to the accompanying drawings in which elements corresponding to one another are given identical reference symbols and in which:

FIG. 1 shows a process flowchart to explain a method for producing a piezoelectric component according to a first exemplary embodiment of the invention;

FIG. 2 shows a piezoelectric component according to a second exemplary embodiment of the invention in a diagrammatic sectional illustration;

FIG. 3 shows a process flowchart to explain methods for producing a piezoelectric component according to possible embodiments of the invention; and

FIG. 4 shows a piezoelectric component according to a third exemplary embodiment of the invention in a diagrammatic sectional illustration.

### DETAILED DESCRIPTION

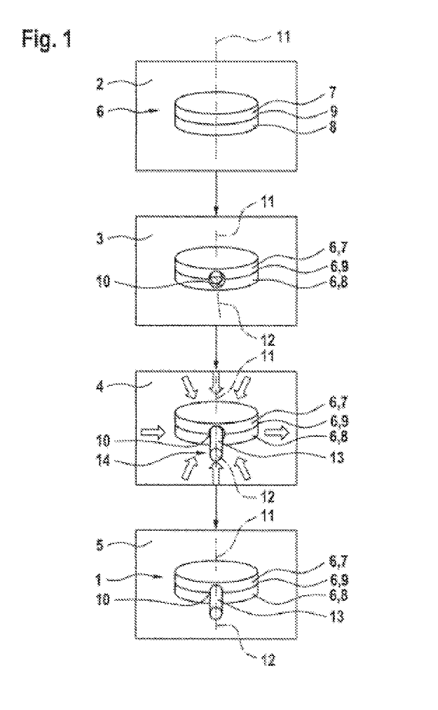

FIG. 1 shows a process flowchart to explain a method for producing a piezoelectric component 1 according to a first exemplary embodiment. The piezoelectric component 1 may be configured, in particular, as piezoelectric sensor 1 or piezoelectric actuator 1. In particular, the piezoelectric component 1 may be used in fuel injection systems. For example, a piezoelectric sensor 1 can serve as a needle-closing sensor which monitors closing of a valve needle of a fuel injection valve. In this case, the sensor 1 can also measure a pressure profile inside a fuel space of the fuel injection valve. Such a sensor 1 may also be configured as a combustion space pressure sensor which measures the pressure in a combustion space of an internal combustion engine directly or indirectly. However, the piezoelectric sensor 1 is also suitable for other applications, particularly in the motor vehicle sector. In particular, the sensor 1 may also be used as a utility sensor for hydraulic or pneumatic applications.

The process flowchart illustrated in FIG. 1 reveals method steps 2, 3, 4, 5. In method step 2, a green product 6 is produced, which is built up from a first ceramic layer 7, a second ceramic layer 8 and an internal electrode layer 9. A basic body 6 of the piezoelectric component 1 is formed from the green product 6. However, the basic body 6 is still in a green state in method step 2.

In method step 3, which follows method step 2, a bore 10 is formed in the green product 6 or basic body 6. The bore 10 is in this case provided in the region of the internal electrode layer 9.

The basic body 6 has an axis 11. During operation, where appropriate, action upon the piezoelectric component 1 takes place along the axis 11, in order to generate a measuring voltage or the like. Where appropriate, expansion of the piezoelectric component 1 along the axis 11 can also be used in order to generate an adjusting force when the piezoelectric component 1 is configured as an actuator 1.

In this exemplary embodiment, an axis 12 of the bore 10 is oriented perpendicularly to the axis 11. The axis 12 of the bore 10 is thereby oriented parallel to the internal electrode layer 9.

In method step 4, which follows method step 3, an electrical contact element 13 is inserted partially into the bore 10. An exposed portion 14 of the electrical contact element 13 in this case remains outside the bore 10 of the green product 6. The green product 6 subsequently has its binder removed and is sintered. As a result of sintering, the green product 6 shrinks The electrical contact element 13 is thereby clamped in the bore 10. The electrical contact element 13 is thus fastened mechanically in the bore 10 of the basic body 6. Moreover, an electrical connection between the electrical contact element 13 and the internal electrode layer 9 is thereby made. In this exemplary embodiment, the electrical connection is directly between the electrical contact element 13 and the internal electrode layer 9.

In method step 5, which follows method step 4, the piezoelectric component 1 is illustrated after sintering. In this case, the space remaining in order to insert the contact element 13 into the bore 10 has disappeared because of shrinkage. The material of the green product 6 has in this case adapted to the contour of the electrical contact element 13. The electrical contact element 13 may be formed by a pin, a wire or the like. Materials which can be used for the electrical contact element 13 are, for example, nickel, copper, silver, palladium, gold or platinum. A suitable alloy with one or more of these materials is also advantageous.

In the production of the piezoelectric component, it is advantageous that the electrical contact element 13 can be introduced into the green product 6 at a very early stage during production, as is described by means of method step 4. As a result, the electrical contact element 13 can be introduced even before the removal of binder and sintering of the piezoceramic material for the ceramic layers 7, 8. A reliable contacting of the internal electrode layer 9 is thus possible even without an additive. The sinter shrinkage of the green product 6 is in this case utilized to make the mechanical and electrical connection.

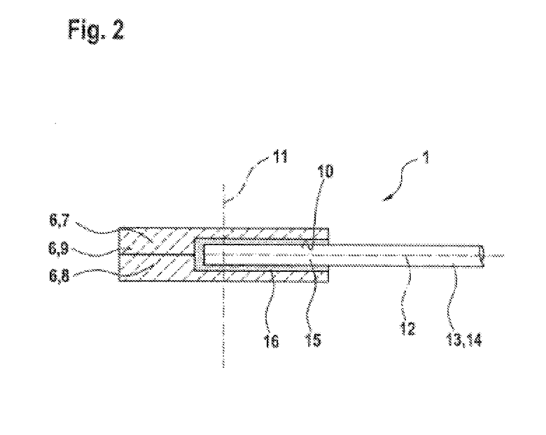

FIG. 2 shows a piezoelectric component 1 according to a second exemplary embodiment in a diagrammatic sectional illustration. The electrical contact element 13 is inserted partially into the bore 10. In this case, a connecting portion 15 of the electrical contact element 13 is located in the bore 10 of the basic body 6. The exposed portion 14 of the electrical contact element 13 is located outside the bore 10. The connecting portion 15 of the contact element 13 is in this case oriented perpendicularly to the axis 11. The connecting portion 15 is thus oriented parallel to the internal electrode layer 9.

In this exemplary embodiment, the electrical contact element 13 is fastened in the bore 10 of the basic body 6 by means of an additive 16. The additive 16 is in this case in the form of an electrically conductive additive 16. The additive 16 may be formed, for example, from a metalizing paste which is introduced into the bore 10 before the removal of binder and before sintering. However, in a modified embodiment, the additive 16 may be introduced into the bore 10 even after the removal of binder from the green product 6 and the sintering of the latter.

Moreover, an electrical connection between the electrical contact element 13 and the internal electrode layer 9 is formed by the electrically conductive additive 16. Thus, in this exemplary embodiment, the electrical contact element 13 is connected to the internal electrode layer 9 indirectly in the bore.

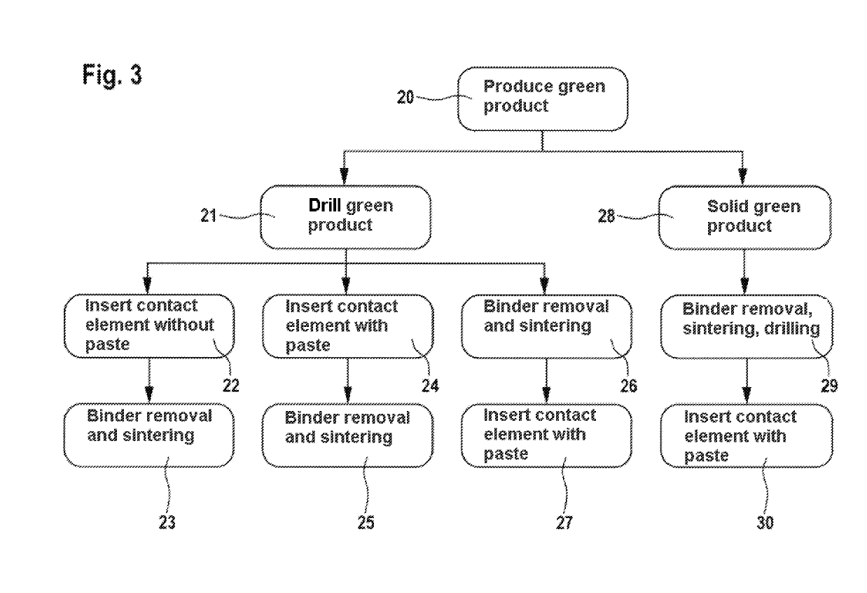

FIG. 3 shows a process flowchart to explain methods for producing a piezoelectric component 1 according to possible embodiments. Here, the method steps 20 to 30 are illustrated, which are run through, according to the embodiment selected in each case, along the arrows illustrated. In this case, the following catchwords are assigned.

Method step 20: “Produce green product”;

Method step 21: “Drill green product”;

Method step 22: “Insert contact element without paste”;

Method step 23: “Removal of binder and sintering”;

Method step 24: “Insert contact element with paste”;

Method step 25: “Removal of binder and sintering”;

Method step 26: “Removal of binder and sintering”;

Method step 27: “Insert contact element with paste”;

Method step 28: “Green product solid”;

Method step 29: “Removal of binder, sintering, drilling” and

Method step 30: “Insert contact element with paste”.

In method step 20, the green product 6 is produced, and in this case this may be formed from a plurality of ceramic layers 7, 8 and at least one internal electrode layer 9. After method step 20, either method step 21 or method step 28 can be selected.

In method step 21, the green product 6 is drilled. The bore 10 is thereby formed. Method step 21 is followed by one of method steps 22, 24, 26.

In method step 22, the electrical contact element 13 is inserted directly without a paste into the bore 10 of the green product 6. In method step 23, which follows method step 22, the green product 6, together with the electrical contact element 13 inserted into the bore 10, has its binder removed and is sintered. The piezoelectric component 1 is thereby produced.

In a further possible embodiment, method step 21 is followed by method step 24. In method step 24, the electrical contact element 13 is inserted into the bore 10 of the green product 6 with a paste 16 from which the additive 16 is formed. Subsequently, the green product 6, together with the additive 16 and electrical contact element 13 inserted into the bore 10, has its binder removed and is sintered in method step 25. The piezoelectric component 1 is thereby formed. In this embodiment, the electrical contact element 13 is connected electrically to the internal electrode layer 9 by means of the electrically conductive additive 16. Furthermore, the electrical contact element 13 is fastened in the bore 10 by means of the additive 16.

In a further possible embodiment, method step 21 is followed by method step 26. In method step 26, the green product 6 provided with the bore 10 has its binder removed and is sintered. A sintered basic body 6 having a bore 10 is thereby formed. Subsequently, the electrical contact element 13 is inserted by means of the additive 16 into the bore 10 of the sintered basic body 6. The additive 16 may in this case be formed from a paste, in particular a metalizing paste. Thus, in this case, the electrical contact element 13 is fastened mechanically in the bore 10 by means of the additive 16. Moreover, an electrical connection of the electrical contact element 13 to the internal electrode layer 9 is in this case ensured via the electrically conductive additive 16.

In a further possible embodiment, method step 20 is followed by method step 28. In method step 28, the solid green product 6 is produced without a bore 10. In method step 29, which follows method step 28, the solid green product 6 has its binder removed and is sintered. Moreover, in method step 29, the bore 10 is formed by drilling the sintered basic body 6 only after the removal of binder and sintering.

In method step 30, which follows method step 29, the electrical contact element 13 is fastened in the bore 10 via an additive 16. An electrical connection of the electrical contact element 13 to the internal electrode layer 9 is also ensured in this case via the electrically conductive additive 16. The additive 16 may in this case be formed from a paste, in particular a metalizing paste.

The contact element 13 can thus be fixed in the piezoelectric basic body 6 with the aid of electrically conductive pastes, in particular metalizing pastes. In this case, the bore 10 can be made either in the green product 6 or in the sintered basic body (sintered product) 6. Furthermore, the metalizing paste can be applied either before or after sintering.

A single electrical contact element 13 or a composite structure formed from the electrical contact element 13 and the additive 16 can thus serve for the electrical outer contacting of the internal electrode layer 9. Simple and robust electrical contacting connected firmly to the basic body 6 can thereby be formed.

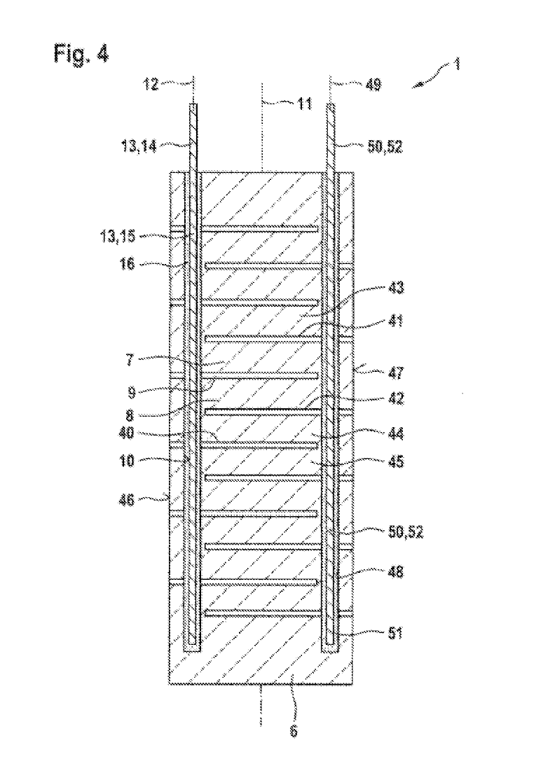

FIG. 4 shows a piezoelectric component 1 according to a third exemplary embodiment in a diagrammatic sectional illustration. In this exemplary embodiment, an axis 12 of the bore 10 is oriented parallel to the axis 11 of the piezoelectric component 1. The bore 10 consequently extends perpendicularly to the internal electrode layer 9.

Moreover, in this exemplary embodiment, the basic body 6 has a multiplicity of internal electrode layers 9, 40, 41, 42, of which only the internal electrode layers 9, 40, 41, 42 are identified in FIG. 4 in order to simplify the illustration. Moreover, the basic body 6 has a multiplicity of ceramic layers 7, 8, 43, 44, 45, of which only the ceramic layers 7, 8, 43, 44, 45 are identified in FIG. 4 in order to simplify the illustration.

The internal electrode layers 9, 40, 41, 42 are in each case formed between adjacent ceramic layers 7, 8, 43, 44, 45. In this case, the internal electrode layers 7, 8, 40, 41, 42 extend only partially over a cross section of the basic body 6. The internal electrode layers 9, 40 extend as far as one side 46 of the basic body 4 and are spaced apart from a side 47. On the other hand, the internal electrode layers 41, 42 extend as far as the side 47, but the internal electrode layers 41, 42 are spaced apart from the side 46.

In this exemplary embodiment, furthermore, a further bore 48 is formed in the basic body 6. An axis 49 of the bore 48 is in this case likewise oriented parallel to the axis 11 of the basic body 6.

The electrical contact element 13 is connected electrically to the internal electrode layers 9, 40 via the additive 16.

A further electrical contact element 50 is arranged in the bore 48. In this case, an additive 51 is likewise provided, by means of which the electrical contact element 50 is fastened mechanically at its connecting portion 52 in the bore 10. Furthermore, the further electrical contact element 50 is connected electrically to the internal electrode layers 41, 42 via the electrically conductive additive 51. An exposed portion 52 of the electrical contact element is located outside the bore 48.

Alternate electrical contacting of a plurality of internal electrode layers 9, 40, 41, 42 can thus be achieved in this way.

The invention is not restricted to the exemplary embodiments described.

1. A piezoelectric component (1) with a basic body (6) which has a first ceramic layer (7), a second ceramic layer (8) and an internal electrode layer (9), the internal electrode layer (9) being provided at least partially between the first ceramic layer (7) and the second ceramic layer (8), the basic body (6) having a bore (10) which is provided at least partially in a region of the internal electrode layer (9), and an electrical contact element (13) being inserted at least partially into the bore (10) of the basic body (6) and being connected electrically at least indirectly to the internal electrode layer (9) in the bore.

2. The piezoelectric component according to claim 1, characterized in that the electrical contact element (13) is fastened in the bore (10) of the basic body (6) by clamping.

3. The piezoelectric component according to claim 1, characterized in that the electrical contact element (13) is fastened in the bore (10) of the basic body (6) by means of an additive (16).

4. The piezoelectric component according to claim 3, characterized in that the additive (16) is in the form of an electrically conductive additive, and in that the electrical contact element (13) is connected electrically to the internal electrode layer (9) by means of the electrically conductive additive (16).

5. The piezoelectric component according to claim 1, characterized in that an axis (12) of the bore (10) is oriented at least approximately parallel to the internal electrode layer (9).

6. The piezoelectric component according to claim 1, characterized in that at least one further internal electrode layer (40) is provided, in that the bore (10) is provided at least partially in a region of the further internal electrode layer (40), and in that an axis (12) of the bore (10) is oriented at least approximately perpendicularly to the internal electrode layer (9) and to the further internal electrode layer (40).

7. A method for producing a piezoelectric component (1) a green product (6) for a basic body (6) of the component (1) being produced, which has a first ceramic layer (7), a second ceramic layer (8) and an internal electrode layer (9) which is provided at least partially between the first ceramic layer (7) and the second ceramic layer (8), the method comprising forming in the basic body (6) a bore (10) which is provided at least partially in the region of the internal electrode layer (9), inserting an electrical contact element (13) at least partially into the bore (10) of the basic body (6), and connecting the electrical contact element at least indirectly to the internal electrode layer (9) in the bore (10).

8. The method according to claim 7, characterized in that the bore (10) is introduced into the green product (6).

9. The method according to claim 8, characterized in that the electrical contact element (13) is introduced at least partially into the bore (10) of the green product (6) directly, and in that the green product (6), together with the electrical contact element (13) introduced into the bore (10), is sintered, the electrical contact element (13) being fastened directly in the bore (10) of the basic body (6) by virtue of sinter shrinkage of the green product (6).

10. The method according to claim 8, characterized in that the electrical contact element (13) is introduced at least partially into the bore (10) of the green product (6) by means of a paste (16), and in that the green product (6), together with the electrical contact element (13) introduced into the bore (10) by means of the paste (16), is sintered, the electrical contact element (13) being fastened in the bore (10) of the basic body (6) by means of the additive (16) formed from the paste (16).

11. The method according to claim 8, characterized in that the green product (6), into which the bore (10) is introduced, is sintered, and in that the electrical contact element (13) is inserted at least partially into the bore (10) of the basic body (6) by means of an additive (16) after sintering, the electrical contact element (13) being connected to the basic body (6) in the bore (10) by means of the additive (16).

12. The method according to claim 7, characterized in that the green product (6) for the basic body (6) is sintered, and in that the bore (10) is formed in the basic body (6) after sintering.
